(19) United States
(12) Patent Application Publication
(10) Pub. No.: US 2015/0146179 A1
(43) Pub. Date: May 28, 2015

(54) Low energy electron beam lithography

(71) Applicant: Takao Utsumi, Tokyo (JP)

(72) Inventor: Takao Utsumi, Tokyo (JP)

(21) Appl. No.: 13/998,694

(22) Filed: Nov. 25, 2013

(51) Int. Cl. H01L 21/768

(52) U.S. Cl. CPC H01L 21/768
USPC 355/53

(57) ABSTRACT

A low energy electron beam lithography system uses an 2 KeV electron beam of about two hundred microamperes, a 4 Division Complementary Mask (4DCM) formed from a monocrystalline silicon wafer with membranes about 100 nm thick that are surrounded by supporting silicon struts, and spaced about 50 microns from an electron sensitive resist layer about 20 nm thick that covers a nonmetallic conductive layer that covers a semiconductor wafer. Distortions in the 4DCM and semiconductor wafer are sensed and an error distortion signal is generated that results in the electron beam being tilted so as to compensate for the distortions to minimize image placement errors.

### FIELD OF THE INVENTION

This invention relates to the manufacture of integrated circuit devices with minimum feature sizes down to about 10 nm to 20 nm, and more particularly, to apparatus and a method for use in such manufacture.

### BACKGROUND OF THE INVENTION

A critical part of the manufacture of integrated circuit devices is the patterning of various layers on the surface of the semiconductor wafer, which after processing is diced up to provide the integrated circuit devices. These patterns define the various regions in the integrated circuit device, such as ion implantation regions, contact window regions, bonding pad regions, etc., and are generally formed by transferring patterns of geometric shapes in a mask to a thin layer of radiation resistive material, termed the “resist”, that overlies the silicon wafer within which are to be formed the integrated circuit devices. Typically the pattern on the mask is on an enlarged scale and needs to be reduced for incidence on the resist.

Presently the pattern transfer process is generally performed by photolithography and the radiation used for the transfer is energy at optical wavelengths.

As the size of features in the pattern to be made in the resist has decreased, as the result of higher packing density of circuit elements in the integrated circuit, there has been a need to decrease correspondingly the wavelength of the optical radiation used for the transfer. It appears that the technology is rapidly approaching the limit at which optical radiation can serve usefully as the radiation needed to pattern the resist appropriately.

There are several alternatives that are currently being considered for use in the transfer of geometric patterns on a mask to the resist layer including the use of extreme ultraviolet radiation, and electron beams.

Electron beams, which have the promise of precise control with fine detail, currently are being used primarily in the preparation of the masks used in optical lithography. While there is also some use of electron beams for direct writing of patterns on resists, on silicon wafers, such use is limited to custom circuits that are made in small runs and sold at very high prices.

A recognized difficulty with the use of electron beams for use in patterning resists in the manufacture of integrated circuits is the low throughput of such use, that is compounded by the relatively high cost of electron beam exposure systems. Accordingly, the potential of electron beam exposure systems for use in the manufacture of integrated circuits is generally deemed not promising and the effort to develop commercial systems for such use has been limited.

In a paper entitled “High Throughput Submicron Lithography with Electron Beam Proximity Printing”, published in September 1984, Solid State Technology, pps 210-217, there is described an electron beam lithography system in which the electron beam is operated with an energy of 10 KeV, which was deemed very low at that time, with a stencil mask that was 2 microns thick, a thickness that was then thinner than was conventional, and with a separation between the mask and wafer of 0.5 millimeters (500 microns) which was then deemed unusually close. The electron beam, which had a diameter of about 1 millimeter (1000 microns), only a small fraction of the area of the mask, was raster scanned across the mask by a first pair of deflection coils. A second pair of deflection coils was used to tilt the beam about a pivot point in the mask plane. A silicon wafer that included a central membrane that was thinned to 2 microns served as the mask. With such a mask and a beam energy of 10 KeV it was necessary to include an absorber layer of a suitable metal on the mask to intercept electrons that were not directed at openings in the mask. Otherwise such electrons would have passed through the thin silicon mask membrane and would have blurred the pattern to be formed on the resist. However, the use of a thicker silicon mask makes it more difficult to achieve narrow line widths because of the high aspect ratio of the line width versus the thickness of the mask.

However, this paper appeared to have little impact on workers in the field and effort on such proximity projection printing systems languished since 1984. Instead, the work on electron beam exposure systems generally has involved systems that employ high energy electrons in the beam to provide “stiffness” to the beam. A stiff beam is one whose diameter is well controlled and so better amenable to focusing and creating sharp images, and also less affected by stray fields. Stiffness is generally related to the energy or velocity of the electrons in the beam, the higher the energy the stiffer the beam.

For this reason, the commercial practice generally has been to use beams of at least 50 KeV in energy for very fine resolution, especially if currents large enough for fast writing are to be used. Apparatus employing such beams generally include: a source of such electrons, an illumination system that focuses and shapes such electrons into a beam and passes the beam through a mask and a projection system that projects such beams through a lens, all the while reducing the mask pattern, by a factor of five to twenty five, before it impinges on the resist.

However, it appears that, as the density of circuit elements in the integrated circuit are increased and the feature size of the pattern in the resist decreases, problems arise with the use of high energy beams. In particular, there is increased the proximity effect, which results in deformation of the pattern formed in the resist as the result of back scattering of electrons from the underlying silicon wafer substrate into the resist. This effect becomes more troublesome the finer the pattern sought to be formed in the resist. There is some evidence that if the accelerating voltages are made high enough, higher energy electrons forward scatter less in the resist and the back scattered electron scatter via a wider area, so that a relatively constant dose results in the resist. This makes the proximity effect correction easier, although it is impossible to eliminate the proximity effect completely. Additionally, it is characteristic of electron beam resists that their sensitivity tends to decrease the higher the energy of the electrons in the beam since the more energetic or faster electrons spend less time and deposit low energy in the resist. Accordingly, the more energetic the electrons, the larger the current (i.e., the higher the density of electrons in the beam) required for a given sensitivity. Moreover, the higher the density of electrons in the beam, the larger the space charge effects, which tend to defocus the beam, which causes a blurring of the pattern and deterioration of the resolution of the pattern. Moreover, the larger the current, the higher the heating of the mask, the resist layer, and the substrate, the greater the distortion of the projected pattern. Therefore one has to limit the operating current in order to maintain the required accuracy. This, in turn, limits the throughput of the apparatus.

To meet some of these problems, fresh interest developed for a time in the use of low energy electron beams for patterning resists. In particular, a paper entitled “Low voltage alternative for electron beam lithography” J Vac. Sci Tech B 10 (6), November/December 1992, pps 3094-3098, describes experiments that demonstrate that proximity effects can be substantially reduced by using electrons of relatively low energy in the beam. In particular, it reports that the proximity effect was substantially reduced with electron beam energies of 2 KeV used on a silicon substrate with a PMMA resist 66 nanometers thick. The work was intended primarily to show that low energy electron beams were potentially useful to expose resists sufficiently thick to be useful for patterning. It recognizes, however, that low voltage has some drawbacks such as a tendency of low brightness of the electron beam and a difficulty of the application of the ultra-thin resist layer.

As a consequence, although it has long been recognized that low energy electron beams are feasible for patterning resists and have some potential advantages, the disadvantages were thought to outweigh the advantages and widespread commercial use on high volume devices has failed to result. Nevertheless, there have been substantial development efforts recently to utilize low voltage lithography by the use of 1. retarding field electron optical column, 2. multiple arrayed miniature electron beam columns, and 3. multiple arrayed scanning tunneling microscope tips.

On Oct. 31, 1997 the present inventor filed a patent application entitled “LOW ENERGY ELECTRON BEAM LITHOGRAPHY” that became U.S. Pat. No. 5,831,272 that issued on Nov. 3, 1998. Corresponding applications were filed in Japan and Germany and a Japanese patent and a German patent were issued. One embodiment of the system of U.S. Pat. No. 5,831,272 is a system for patterning a resist on a semiconductor substrate. The system comprises a 1X stencil mask of monocrystalline silicon positioned in the path of the electron and an electron-beam sensitive resist-covered substrate in the path of the electron beam and the mask. The resist is thin, the voltage accelerating the beam is sufficiently low such that the proximity effect is insignificant, the power of the beam is sufficiently low such that heating of the mask, resist, and substrate is also insignificant, and the density of electrons in the beam is sufficiently low that space charge effects are insignificant. The electron beam accelerating voltage is about 2 KeV, with a range of about 1 to 5 KeV, the mask is positioned about 50 microns from the resist covered substrate, the resist is about 100 nm thick, with a range of 30 to about 300 nm, the current of the electron beam is about 3 microamperes, with a range of about 0.3 to about 20 microamperes, the beam diameter is about 1.0 millimeter, with a range of about 0.1 to about 5 millimeter, and the mask is a stencil mask having a thickness of about 500 nm, with a range of about 200 to 1000 nm. Alignment errors of the mask and semiconductor wafer were kept down to about 15 nm. By 2007 the LOW ENERGY ELECTRON BEAM LITHOGRAPHY system of U.S. Pat. No. 5,831,272 had been built, tested, and found to be functional. Using this system it was found that feature sizes well below 1 micron and potentially down to about only 45 nm. It took a substantial amount of testing to determine the limit of how small feature sizes could be achieved while keeping throughput at a high enough level to be commercially viable.

Between 1997 and the present there has been considerable work on improving conventional systems (i.e., ArF Immersion Lithography) for transferring an image contained on a mask to a semiconductor wafer to form an integrated circuit that was meant for high volume production. This technology, which has become wide spread, has resulted in systems that can generate integrated circuits for high volume production with features down to about 40 nm.

The present invention represents a substantial improvement in the results obtainable using the apparatus of U.S. Pat. No. 5,831,272 which is incorporated herein by reference. While much of the apparatus of the present invention is common with the inventors previous invention, there are significant changes to the apparatus and the operating parameters resulting from the sixteen years of work by the present inventor on improving his earlier invention.

In the next few years it is desirable to further improve lithographic systems that can generate integrated circuits with features in a range of about 10 to 20 nm. One such feature might be the length of a gate of a Metal-Oxide-Silicon transistor or the wide of a metal conductor. These proposed systems, such as ArF double patterning and EUV lithography systems, are complex and expensive and it is not clear which, if any, will actually go into wide spread use.

### SUMMARY OF THE INVENTION

The present invention is directed to a system for low energy electron beam proximity projection lithography with a sufficient throughput and accuracy for patterning minimum feature size in the range of about 10 to 20 nm for mass produced integrated circuits.

Viewed from one aspect, the present invention is a system for patterning an electron sensitive resist layer covering a semiconductor wafer. The system comprises an electron beam system characterized by an accelerating voltage of about 0.5 to about 5 KeV, an electron beam current of about 50 to about 800 microamperes, the beam has a diameter of about 1 to about 9 mm, and fine deflectors for adjusting tilt of the electron beam. It further comprises an n Division Complementary Mask (nDCM), where n is an integer greater than 2, having struts that surround and support each membrane that has formed therein a pattern that is to be transferred to the resist layer, the thickness of the resist layer being about 10 to about 300 nm, and the thickness of each membrane is about 50 to about 500 nm, the nDCM and the resist layer are spaced about 10 to about 300 microns from each other and are positioned in the path of the electron beam. The resist layer has a thickness of about 10 to 300 nm.

The system further comprises a nonmetallic conductor layer having a thickness of about 50 to 500 nm and lying under the resist layer.

The system further comprises a distortion sensor and tilt means. The distortion sensor means senses for distortions in the membranes and the semiconductor wafer. The tilt means has an input coupled to an output of the distortion sensor means for generating a distortion error correction signal at an output thereof that is coupled to inputs of the fine deflectors such that distortions in the membranes of the nDCM and the semiconductor wafer are compensated for so as to minimize image placement errors.

Viewed from a second aspect, the present invention is a system for forming a pattern on a electron sensitive resist layer covering a chip semiconductor wafer having a plurality of areas into each of which an individual integrated circuit is to be formed. The system comprises an electron beam system characterized by an accelerating voltage of about 0.5 to about 5 KeV, an electron beam current of about 50 to about 800 microamperes, the beam has a diameter of about 1 to about 9 mm, and fine deflectors for adjusting tilt of the electron beam.

The system further comprises a mask semiconductor wafer comprising a plurality of n Division Complementary Masks (nDCMs), where n is an integer greater than 2, each of the nDCMs has struts that surround and support a membrane that has formed therein a pattern that is to be transferred to the resist layer, the thickness of each membrane is about 50 to about 500 nm, and the mask semiconductor wafer and the chip semiconductor wafer are spaced about 10 to about 300 microns from each other and are positioned in the path of the electron beam. The resist layer has a thickness of, about 10 to about 300 nm.

The system further comprises a nonmetallic conductor layer, distortion sensor means, and tilt means. The nonmetallic conductor layer has a thickness of about 50 to 500 nm and is under the resist layer. The distortion sensor means senses distortions in the membranes and the chip semiconductor wafer. The tilt means, which has an input coupled to an output of the distortion sensor means, generates a distortion error correction signal at an output thereof that is coupled to inputs of the fine deflectors such that distortions in the membranes and the chip semiconductor wafer are compensated for so as to minimize image placement errors.

Viewed from a third aspect, the present invention is a process, in the manufacture of silicon integrated circuits, of patterning an electron sensitive resist layer covering a nonmetallic conductor layer that covers a semiconductor wafer. The process comprises the steps of:

Using an electron beam system having an accelerating voltage in the range of about 0.5 to about 5 KeV with a beam current in the range of about 50 to 800 microamperes and with the beam diameter being in the range of about 1 to 9 mm, aligning a mask that contains a pattern that is to be transferred to the resist layer with the semiconductor wafer. The mask and the semiconductor wafer are in the path of the electron beam and are separated from each other by 10 to 300 microns. The thickness of the resist layer is about 10 to 300 nm. The mask is an n Division Complementary Mask (nDCM), where n is a whole integer greater than 2. The nDCM has struts that surround and support membranes that have formed therein the pattern that is to be transferred to the electron sensitive resist layer. The membranes having a thickness in the range of about 50 to about 500 nm.

Sensing distortions in the nDCM and the semiconductor wafer and generating therefrom a distortion error correction signal.

Applying the error correction signal to fine deflectors of the electron beam system that control tilt of the electron beam so as to adjust the tilt of the beam to compensate for distortions in the nDCM and wafer so as to minimize image placement errors.

Scanning the electron beam across the membrane with an accelerating voltage in the range of about 0.5 to about 5 KeV, a beam current in the range of about 50 to 800 microamperes and with the beam diameter being in the range of about 1 to 9 mm, whereby the pattern in the membranes is transferred to the resist layer.

The invention will be better understood from the following more detailed description taken in conjunction with the accompanying drawing. The drawings are not necessarily to scale.

### BRIEF DESCRIPTION OF THE DRAWING

FIG. 1 shows schematically a low energy electron beam lithography system in accordance with the present invention;

FIG. 2 shows a three dimensional view of a mask structure useful with the system of FIG. 1;

FIG. 3 shows a cross-sectional view of a membrane and two supporting struts of the mask structure of FIG. 1 separated from an electron sensitive resist layer that covers a semiconductor wafer in accordance with the present invention;

FIG. 4 shows an example of an integrated circuit pattern;

FIG. 5 shows key portions of a 4 Dimensional Complementary Mask (4DCM) structure having the pattern of FIG. 4 formed therein in accordance with the present invention;

FIG. 6 shows a semiconductor wafer with a plurality of integrated chip areas in which the pattern formed in the 4 Dimensional Complementary mask (4DCM) of FIG. 5 is to be formed;

FIG. 7 shows a chip semiconductor wafer which comprises a plurality of rows and columns of areas which are to each receive a pattern and become an integrated circuit; and

FIG. 8 shows a mask semiconductor wafer which comprises a plurality of rows and columns of mask areas that each contain a pattern that is to be transferred to areas of the chip semiconductor wafer in accordance with the present invention.

### DETAILED DESCRIPTION

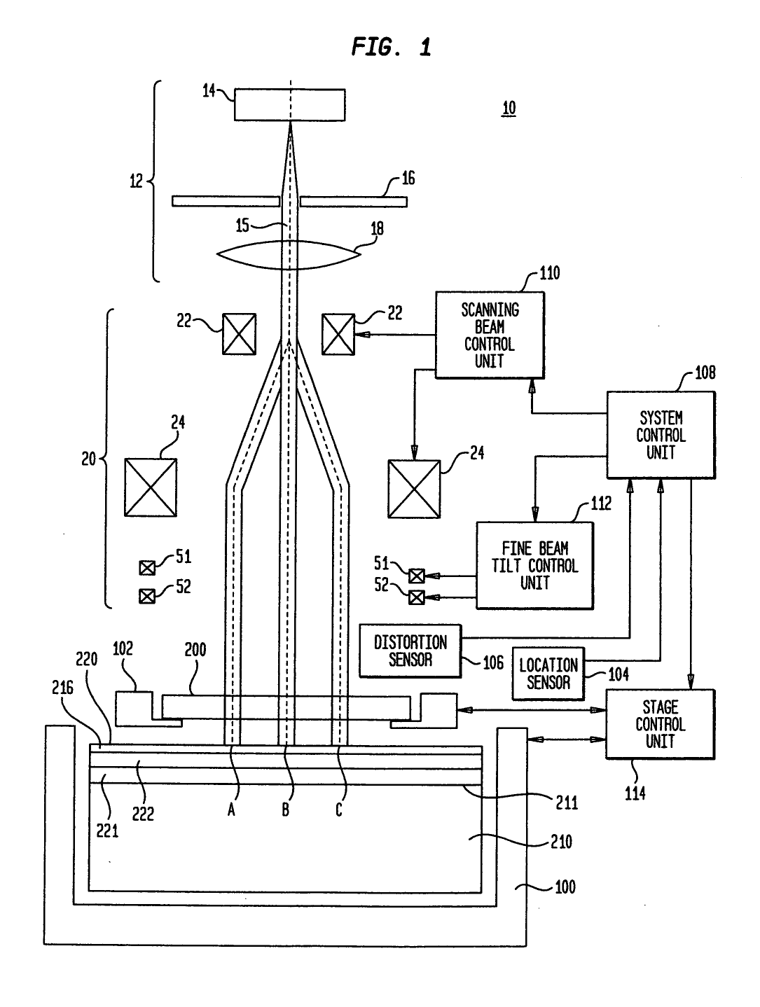

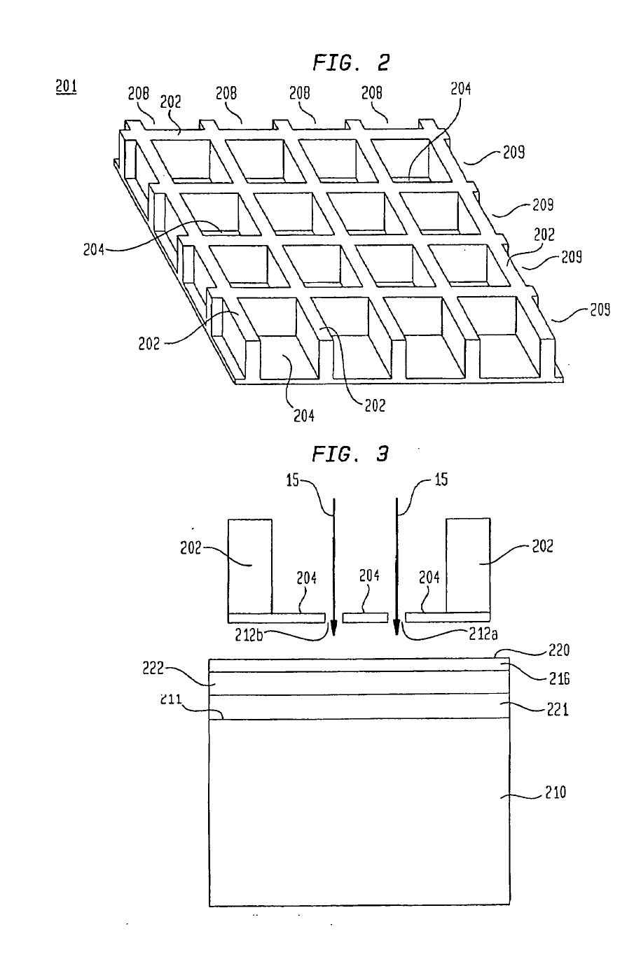

Referring now to FIG. 1, there is shown a system (electron beam apparatus) 10 in accordance with the present invention. System 10 comprises an electron gun 12 including an electron source 14 that provides abeam of electrons 15, a beam limiting aperture 16 which essentially forms a circular beam, and a condensing lens 18 that forms the electrons into an essentially parallel beam, a scanning projection system 20 including first and second main (primary) sets 22 and 24 of deflecting coils (or electrodes) for deflecting the beam as an essentially parallel beam in either a raster or a vector scan mode over and essentially normal to a surface of a mask structure 200 shown in block form. A preferred embodiment of the mask structure 200 is shown in more detail in FIGS. 2 and 3 and is denoted as an n Dimensional Complimentary Mask (nDCM). In a preferred embodiment n=4 and mask structure 200 is denoted as a 4DCM. The is an integer greater than 2. The drawing shows the electron beam 15 in three separate positions A, B, and C which represents a scanning mode of operation.

The system 10 further comprises first and second fine tuning sets of deflecting coils (or electrodes) 51 and 52, which are also denoted as fine deflectors 51 and 52. Deflecting coils 51 and 52 are used to tilt the beam slightly (i.e., a fine tune) at the pivot on the mask structure 200 plane for the purpose of compensating for distortions in the mask structure 200 and the wafer 210 that limit pattern placement accuracy. Spaced about 50 microns below the mask structure 200 is a workpiece comprising a relatively large semiconductor wafer (substrate) 210 of monocrystalline silicon. Covering a top surface 211 of wafer 210 is an optional planarizing insulator layer 221, typically photo-resist, that is covered by a conductive layer 222, that is covered by an ultra thin electron sensitive resist layer 216 having a top surface 220 that is to be patterned. The layer 222 is a nonmetallic conductor, typically a hydro-carbon resist like material or amorphous carbon. The electron sensitive resist layer 216, in a preferred embodiment, is about 20 nm thick, and can be in a range of about 10 to about 300 nm. It can be any of the resists amenable at ultrathin thicknesses to patterning by an electron beam. Layer 222 is typically about 50 nm thick but can be thicker. In a preferred embodiment the operating beam voltage is about 2 KeV with a range of about 0.5 to about 5 KeV, the beam current is about 200 microamperes with a range of about 50 to about 800 microamperes.

System 10 further comprises a system control unit 108, a scanning beam control unit 110, a fine beam tilt control unit 112, a stage control unit 114, a distortion sensor 106 (also denoted as distortion sensor means), a location sensor 104, high precision wafer stage 100, and a high precision mask stage 102. System control unit 108 comprises a computer and memory. Arrows on lines typically show the direction of the flow of information (signals). The opposite sided arrows on the lines from stage control unit 114 indicate that a mechanical force is exerted pushing and/or pulling mask stage 102 and wafer stage 100. The fine beam tilt control unit 112 and portions of the system control unit 108 may be denoted as tilt means.

The semiconductor wafer 210 is supported on the high precision wafer stage 100 that allows the wafer 210 to be stepped in the usual fashion so that successive areas the resist-covered wafer 210 can be exposed in turn to the electron beam 15 for a time appropriate for patterning the resist layer 216. The mask structure 200 is supported on a mask stage 102.

The stage control unit 114 is in mechanical contact with the mask stage 102 and the wafer stage 100. The location sensor 104 senses the exact locations of the mask structure 200 that is being held on the mask stage 102 and the wafer 210 that is being held on the wafer stage 100. An output of the location sensor 104 is coupled to an input of the system control unit 108. Unit 108 receives mask structure 200 and wafer 210 information from the location sensor 104 as to the exact locations of the mask structure 200 on the mask stage 102 and the wafer 210 on the wafer stage 100. It then sends a signal to the stage control unit 114 that causes the wafer stage 100 and mask stage 102 to be moved relative to each other such that the mask structure 200 is aligned with a preselected portion of the wafer 210 to within about 2 nm or less.

The scanning beam control unit 110 is electrically connected to the main deflectors 22 and 24 and controls the scanning of the electron beam 15 through the mask structure 200 and across portions of the electron sensitive resist layer 216 on wafer 210. System control unit 108 has an output connected to an input of scanning beam control unit 110 and controls unit 110.

During processing a semiconductor wafer can get distorted due to induced stresses and how it is held (chucked). During the creation of a mask the processing used to form a pattern thereon and how it is held (chucked) can cause distortions in its surface. In order to achieve very small feature sizes, about 10 nm, it is necessary for alignment of the plane of the mask 200 (membranes 204 shown in FIGS. 2 and 3) and the top surface 220 of resist layer 216 to be within about 3 nm or less, preferably 2 nm or less, and that distortions on the mask 200 and the wafer 210 be compensated for.

The distortion sensor 106 senses distortions in the mask structure 200, specifically in the membrane 204 portion that is shown in detail in FIGS. 2 and 3. It also senses distortions in wafer 210. The distortion information sensed by distortion sensor 106 is coupled via an output of distortion sensor 106 to an input of system control unit 108. An output of system control unit 108 is coupled to an input of fine beam control unit 112 which has outputs connected to deflection coils 51 and 52. A combination of portions of system control unit 100 and fine beam tilt control unit 112 controls the amount of tilt of the electron beam 15 and adjusts same to compensate for the distortions in the mask structure 200, and the wafer 210. This combination is denoted as tilt means. Distortions in mask structure 200 and wafer 210 can cause misregistration of a pattern to be formed on resist layer 216 and thus limit pattern placement accuracy. The combination of portions of system control unit 108 and fine beam tilt control unit 112 result in error correction signals being applied to inputs of fine deflectors 51 and 52. These error correcting signals essentially cancel out the mask structure 200 and wafer 210 distortions and thus allow accurate pattern placement on resist layer 216.

The system 10 further comprises appropriate housing (not shown), typically a vacuum envelope, for enclosing the system. There would also be included the various components (not shown) used to establish the accelerating voltages that are necessary for operation in the manner described.

FIG. 2 shows a three dimensional view of a preferred embodiment of the mask structure 200 of FIG. 1 in accordance with the present invention. Mask structure 201 comprises a plurality of membranes 204 supported by struts 202. There are shown 16 membranes 204 arranged in a four by four matrix with four columns 208 and four rows 209 each containing four membranes 204. Each of the membranes contains openings (holes) there through (not shown in FIG. 2 but shown in FIG. 3). An n Dimensional Complementary Mask (nDCM) contains n groups of membranes 204 each having struts 202 surrounding each membrane 204 with the struts 202 of each of the n groups offset from the struts of the others of the n groups. In a preferred embodiment n=4 such that mask structure 200 is a 4DCM. In a preferred embodiment membranes 204 are about 100 nm thick but can be within a range of about 50 to 500 nm. Struts 202 are substantially thicker, typically by several orders of magnitude, than membranes 204 and provide mechanical support and act as heat sinks for membranes 204.

The 4DCM has many advantages over a single conventional 1X stencil mask. It has greater mechanical stability and higher thermal stability. When the pattern density formed in a particular 1X stencil mask is very high, there can result a hole-opening ratio of 50% which makes it is very difficult to have high pattern placing accuracy. This is particularly true in the case an integrated circuit chip there are areas of very dense patterns close to areas where there are sparse patterns. The use of a 4DCM essentially divides the pattern density by four and makes it feasible to generate 10 to 20 nm features with proper pattern placement accuracy.

The membrane layer 204 can be a conductive material such as doped silicon, silicide, or even a metallic layer. Struts 202 are typically monocrystalline silicon.

FIG. 3 shows a cross-sectional view of a single membrane 204 with its supporting struts 202 positioned above a wafer 210. This represents a partial portion of a 4DCM. For illustrative purposes, there are shown only two openings (holes) 212a and 212b through membrane 204. These represent a portion of a pattern to be transferred to electron sensitive resist layer 216. Electron beam 15 is shown penetrating through holes 212a and 212b and impinging on top surface 220 of ultra thin electron sensitive resist layer 216. The nonmetallic conductor layer 222 helps reduce “charge up” in Low Energy Electron Beam Lithography systems that can degrade the precise image process. Insulator layer 221 (typically photo resist), which is optional, services to planarize a top surface of wafer 210, if needed.

When electron's of relatively low accelerating energy, such a 2 KeV impinging on the ultra-thin electron sensitive resist layer 216, they are not scattered in a wide angle, but go straight down to sensitize a narrow region of resist layer 216. This results in forming a high resolution pattern. Any electrons that pass through layer 216 are essentially trapped in nonmetallic conductor layer 122 which eliminates charge-up effect in the resist layer 216. The struts 202 act as large heat sinks for membranes 204. This helps cool them and thus reduces thermal distortion. This essentially limits the need for complex steps to compensate for distortions of membranes (masks) 204 caused by the electron beam 15 which heats membranes 204.

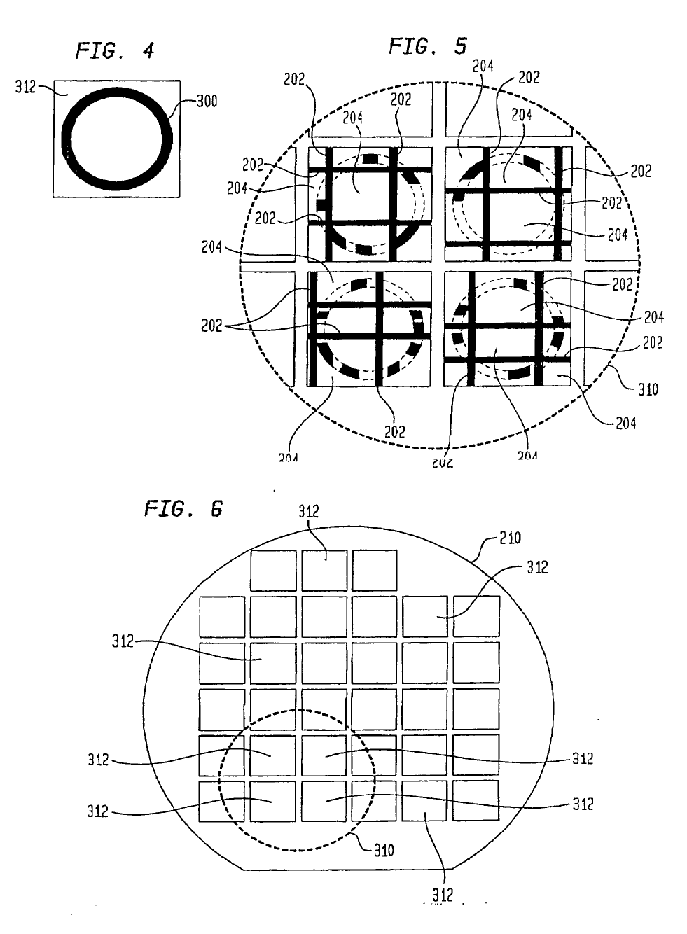

FIG. 4 shows a single integrated circuit 312 with a circle pattern 300 formed therein. Pattern 300 is to be transferred to a 4DCM shown in FIG. 5 and then from the 4DCM of FIG. 5 to each of areas (integrated circuits) 312 on a silicon wafer 210 shown in FIG. 6.

FIG. 5 shows a key portion of a 4DCM fabricated in a silicon wafer 310 that contains the circle pattern 300 of FIG. 4 that is to be transferred to each of areas (integrated circuits) 312 of the wafer 210 of FIG. 6. Each area 312 will be formed into a separate integrated circuit 312. Essentially ¼ of the circle pattern 300 of FIG. 4 has been formed in each of the four portions (each containing membranes 204 and struts 202) of the 4DCM. Each of these four portions of the 4DCM is the same shape and size as an area 312 of wafer 210 of FIG. 6. Wafer 310 is essentially a mask and may be denoted as mask wafer 310. Mask wafer 310 can have multiple 4DCM's each having the same pattern. This makes the transfer of the pattern to individual integrated circuits on a wafer 210 faster.

FIG. 6 shows a semiconductor wafer 210 which comprises a plurality of rows and columns of areas 312. Each of areas. 312 will become a separate integrated circuit into which circle pattern 300 is to be formed. In order to form the circle pattern 300 in each of the areas 312 it is necessary to transfer the pattern portions of all four sections of the 4DCM of FIG. 5 to each of the areas 312. This is achieved as follows: Using the system 10 shown in FIG. 1, the mask wafer 310 is placed on the mask stage 102 and the wafer 210 is placed in the wafer stage 100. The mask stage 102 and the wafer stage 100 are then, as is shown, moved with respect to each other to align the mask wafer 310 over four areas 312 of the semiconductor wafer 210. Electron beam 15 transfers the pattern in each of the four segments of the 4DCM to each of the four areas 312. Mask wafer 310 is then sequentially moved to each of the next four areas 312 until all of the areas 312 have each received one of the four segments of the 4DCM. The process is repeated three more times with the mask wafer 310 moved over a column of areas 312 such that all of the four segments of the mask wafer 210 have been transferred to each of the areas 312.

FIG. 7 shows a semiconductor wafer 710 which comprises a plurality of rows and columns of 28 areas 712. Wafer 710 is denoted as a chip semiconductor wafer 710. Each of 28 areas 712 will become a separate integrated circuit into which a pattern is to be formed.

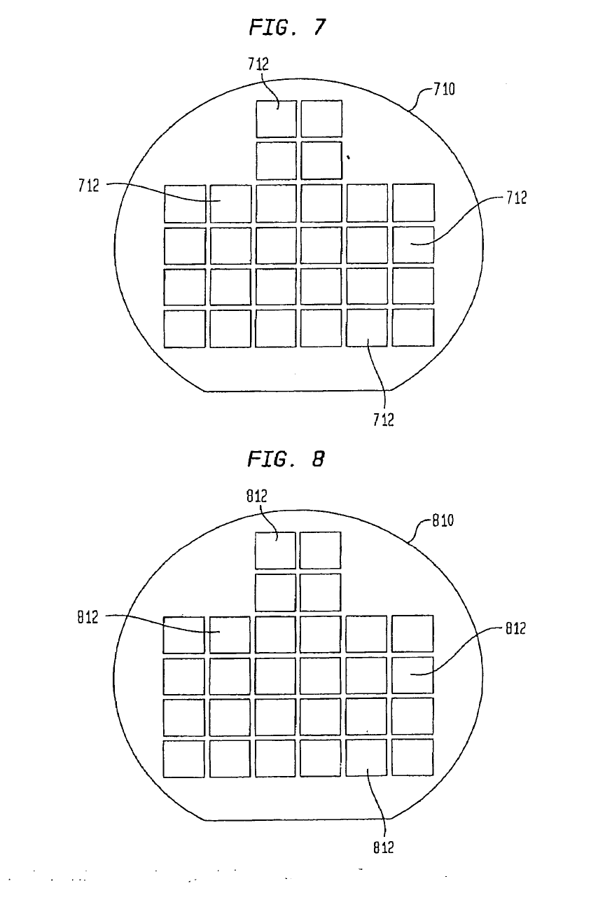

FIG. 8 shows a semiconductor wafer 810 which comprises a plurality of rows and columns of 28 mask areas 812 with each of these areas being the same shape and size as areas 712 of chip semiconductor wafer 710 of FIG. 7. The overall shape and dimensions of chip semiconductor wafer 710 and mask semiconductor wafer 810 are in a preferred embodiment essentially the same. Wafer 810 is denoted as a mask semiconductor wafer 810 since each of the areas 812 thereof comprises a nDCM that has the basic strut structure shown in FIG. 2, i.e., a membrane 204 surrounded by struts 202. In a preferred embodiment each nDCM is a 4DCM which means that it contains 4 membranes 204, each surrounded by struts 202 with the struts of the four membranes offset from each other. Each of the 4 membranes has been patterned (i.e., holes have been formed there through) to contain ¼ of a pattern (pot shown) that is to be transferred to each of 28 areas 712 of chip semiconductor wafer 710 of FIG. 7. There are 7 4DCM's contained on mask wafer 810.

The transfer of a pattern contained in 4DCM's of mask semiconductor wafer 810 to the areas 712 of chip wafer 710 can be accomplished using the mask semiconductor wafer(s) 810 using at least two different methods.

In the first method each of the four sections of the 7 4DCM's of mask wafer 810 all contain the same ¼ of the pattern that is to be transferred to the 28 areas 712 of chip semiconductor wafer 170. A first mask semiconductor wafer 810 is positioned above a chip semiconductor wafer 710 in system 10 of FIG. 1. The mask semiconductor wafer 810 is aligned to the chip semiconductor wafer 710 and the process of transfer described in the description of FIG. 1 is done. This transfers the same ¼ of the selected pattern to each of the 28 areas 712. This mask semiconductor wafer 810 is then removed. A second mask semiconductor wafer 810, in which each of the four sections of each of the 7 4DCM's contains the second ¼ of the pattern to be transferred to the 28 areas 172, is then inserted into the system 10 of FIG. 1 and the described process is repeated. The second mask semiconductor wafer 810 is then removed. A third mask semiconductor wafer 810, in which each of the four sections of each of the 7 4DCM's contains the third ¼ of the pattern to be transferred to the 28 areas 172, is then inserted into the system 10 of FIG. 1 and the described process is repeated. The third mask semiconductor wafer 810 is then removed. A fourth mask semiconductor wafer 810, in which each of the four sections of each of the 7 4DCM's contains the fourth ¼ of the pattern to be transferred to the 28 areas 172, is then inserted into the system 10 of FIG. 1 and the described process is repeated. The fourth mask semiconductor wafer 810 is then removed. All of the 28 areas 712 of chip semiconductor wafer 710 have now received the entire pattern that was to be transferred from mask semiconductor wafers 810. One advantage of this method of transfer is that each of the four mask wafers 810 and the chip semiconductor wafer 710 have moved with respect to each other only once.

In the second method each of the four sections of the 7 4DCM's of mask semiconductor wafer 810 contain a separate ¼ of the pattern that is to be transferred to the 28 areas 712 of chip semiconductor wafer 170. The mask semiconductor wafer 810 is positioned above a chip semiconductor wafer 710 in system 10 of FIG. 1. The mask semiconductor wafer 810 is aligned to the chip semiconductor wafer 710 and the process of transfer, provided in the description of FIG. 1 is done. This transfers. the ¼ of the selected pattern to each of the 28 areas 712. Each area 712 of each two by two adjacent groups of areas 712 receives a separate ¼ of the pattern to be transferred. The mask semiconductor wafer 810 has to then be moved at least three times and re-aligned with the correct portion of the chip semiconductor wafer 710 so as to transfer the remaining three ¼ portions of the pattern to each of the areas 712. One advantage of this method of transfer is that only one mask semiconductor wafer 810 and the chip semiconductor wafer 710 have to be placed in system 10.

The specific values described are merely illustrative of a presently preferred mode of operation and a range of such values can be used without causing any of the specific undesired effects discussed becoming significant. For example, the resist thickness may be in the range between about 10 to 300 nm thick; the accelerating voltage may be in the range from about 0.5 to 5 KeV; the beam diameter may be in the range of about 1 to 9 millimeters; and the distance between the mask and the wafer may be in the range of 10 to 300 microns. In the presently preferred embodiment, the electron sensitive resist layer 216 is about 20 nm thick, the nonmetallic conductor layer 222 is about 50 nm thick, the beam diameter is about 3 millimeter, the mask 200 is a 4 Division Complementary mask (4DCM) with the membrane 204 having a thickness of 100 nm and being spaced about 50 microns from the resist layer 216.

It is to be understood that the specific embodiment described is merely illustrative of the general principles of the invention and that, accordingly, other embodiments may be devised by a skilled worker in the art without departing from the spirit and scope of the invention. For example, as the density of components on integrated circuits increases, it becomes beneficial to use masks of the nDCM type where n equals 5 or a greater integer. Still further, the tilt control unit can be modified by adding computer power and memory such that it can provide the entire tilt means function with the output of the distortion sensor being coupled to it rather than to the system control unit. Furthermore, the physical structure of the mask and wafer stages can be different than shown. For example, each could be a essentially flat surface with the mask and wafer being held in place by electrostatic forces.

1. A system for patterning an electron sensitive resist layer covering a semiconductor wafer comprising:
an electron beam system characterized by an accelerating voltage of about 0.5 to about 5 KV, an electron beam current of about 50 to about 800 microamperes, the beam having a diameter of about 1 to about 9 mm, and fine deflectors for adjusting tilt of the electron beam;
an n Division Complementary Mask (nDCM), where n is an integer 2 or greater, having struts that support each membrane that has formed therein a pattern that is to be transferred to the resist layer, the thickness of the resist layer being about 10 to about 300 nm, and the thickness of each membrane being about 50 to about 500 nm, the nDCM and the resist layer being spaced about 10 to about 300 microns from each other and being positioned in the path of the electron beam;
the resist layer having a thickness of about 10 to 300 nm;
a nonmetallic conductor layer having a thickness of about 50 nm and lying under the resist layer;
a distortion sensor having an output, said distortion sensor being adapted to sense alignment distortions between the membranes of the nDCM and the semiconductor wafer and provide at the output thereof signals representative of alignment distortion errors between the membranes of the nDCM and semiconductor wafer; and
a system control unit having an input coupled to the output of the distortion sensor for controlling overall operation of the system, said system control unit being adapted to generate from signals received from the distortion sensor a distortion error correction signal at an output thereof that is coupled to inputs of the fine deflectors whereby the tilt of the electron beam is adjusted such that alignment distortion errors between the membranes of the nDCM and the semiconductor wafer are compensated for so as minimize image placement errors.

2. The system of claim 1 wherein the electron beam accelerating voltage is about 2 KV, the electron beam current is about 200 microamperes, the electron beam diameter is about 3 mm, the nDCM is a 4 Divisional Complementary Mask (4DCM), the thickness of each membrane of a 4DCM is about 100 nm, the semiconductor wafer being spaced about 50 microns from the 4DCM, and the thickness of the resist layer being about 20 nm.

3. The system of claim 2 wherein the struts of the 4DCM are monocrystalline silicon, are thicker than the membranes and act as heat sinks for the membranes, and the membranes are a conductive layer of one of a group consisting of doped silicon, silicide, and a conductor.

4. The system of claim 1 wherein the nonmetallic conductor layer is one of a group comprising a hydro-carbon resist like material and amorphous carbon.

5. The system of claim 4 wherein the nonmetallic conductor layer is about 50 nm thick.

6. The system of claim 1 wherein the system control unit comprises a computer and memory.

7. The system of claim 6 further comprising a scanning beam control unit having an input coupled to an output of the system control unit and having outputs coupled to primary deflectors of the system.

8. The system of claim 7 further comprising:
a mask stage adapted to support the nDCM;
a wafer stage adapted to support the semiconductor wafer;
the nDCM being positioned on the mask stage; and
the semiconductor wafer being positioned on the wafer stage; and
the mask and wafer stages being movable such that the nDCM and the semiconductor wafer can be aligned.

9. The system of claim 8 further comprising:
a location sensor located near the nDCM and the semiconductor wafer and having an output coupled to an input of the system control unit, the location sensor being adapted to determine the location of the mask stage and the location of the nDCM on the mask stage, and to determine the location of the semiconductor stage and the location of the semiconductor wafer on the mask stage; and
a stage control unit having an input coupled to the system control unit and being mechanically coupled to at least one of the mask and semiconductor stages and being adapted to adjust the position of the mask stage with respect to the semiconductor stage such that the nDCM and the semiconductor wafer are aligned.

10. A system for forming a pattern on a electron sensitive resist layer covering a chip semiconductor wafer having a plurality of areas into each of which an individual integrated circuit is to be formed comprising:
an electron beam system characterized by an accelerating voltage of about 0.5 to about 5 KV, an electron beam current of about 50 to about 800 microamperes, the beam having a diameter of about 1 to about 9 mm, and fine deflectors for adjusting tilt of the electron beam;
a mask semiconductor wafer comprising a plurality of n Division Complementary Masks (nDCMs), where n is an integer 2 or greater, each of the nDCMs having struts that surround and support a membrane that has formed therein a pattern that is to be transferred to the resist layer, the thickness of each membrane being about 50 to about 500 nm, and the mask semiconductor wafer and the chip semiconductor wafer being spaced about 10 to about 300 microns from each other and being positioned in the path of the electron beam;
the resist layer having thickness of about 10 to about 300 nm;
a nonmetallic conductor layer having a thickness of about 50 nm and lying under the resist layer;
a distortion sensor having an output, said distortion sensor being adapted to sense alignment distortions between the membranes of the nDCM and the semiconductor wafer and provide at the output thereof signals representative of alignment distortion errors between the membranes of the nDCM and semiconductor; and
a system control unit having an input coupled to the output of the distortion sensor for controlling overall operation of the system, said system control unit being adapted to generate from signals received from the distortion sensor a distortion error signal at an output thereof that is coupled to inputs of the fine deflectors whereby the tilt of the electron beam is adjusted such that alignment distortion errors between the membranes of the nDCM and the semiconductor wafer are compensated for so as to minimize image placement errors.

11. The system of claim 10 wherein the electron beam accelerating voltage is about 2 KV, the electron beam current is about 200 microamperes, the electron bean diameter is about 3 mm, the thickness of the membranes of the nDCM is about 100 nm, the nDCM being spaced about 50 microns from the resist layer, the thickness of the resist layer being about 20 nm, and each of the nDCMs is a 4 Divisional Complementary Mask (4DCM).

12. The system of claim 11 wherein the struts of the 4DCM are monocrystalline silicon, are thicker than the membranes and act as heat sinks for the membranes, and the membranes are a conductive layer of one of a group consisting of doped silicon, silicide, and a conductor.

13. The system of claim 10 wherein the nonmetallic conductor layer is one of a group comprising a hydro-carbon resist like material and amorphous carbon.

14. The system of claim 13 wherein the nonmetallic conductor layer is about 50 nm thick.

15. The system of claim 10 wherein the number of areas of the chip semiconductor wafer are about the same as the number of nDCMs.

16. In the manufacture of silicon integrated circuits, a process of patterning an electron sensitive resist layer covering a nonmetallic conductor layer that covers a semiconductor wafer comprising the steps of:
using an electron beam system having an accelerating voltage in the range of about 0.5 to about 5 KV with a beam current in the range of about 50 to 800 microamperes and with the beam diameter being in the range of about 1 to 9 mm, aligning a mask that contains a pattern that is to be transferred to the resist layer with the semiconductor wafer, the mask and the semiconductor wafer being separated from each other by about 10 to 300 microns, the thickness of the resist layer being about 10 to 300 nm, the mask being an n Division Complementary Mask (nDCM), where n is a whole integer 2 or greater, the nDCM having struts that support membranes that have formed therein the pattern that is to be transferred to the electron sensitive resist layer, and the membranes having a thickness in the range of about 50 to about 500 nm;
sensing alignment distortions between the nDCM and the semiconductor wafer and generating therefrom an alignment distortion error correction signal;
applying the alignment distortion error correction signal to fine deflectors of the electron beam system that control tilt of the electron beam so as to adjust the tilt of the beam to compensate for alignment distortions between the nDCM and wafer so as to minimize image placement errors; and
scanning the electron beam across the membrane with an accelerating voltage in the range of about 0.5 to about 5 KV, a beam current in the range of about 50 to 800 microamperes and with the beam diameter being in the range of about 1 to 9 mm, whereby the pattern in the membranes is transferred to the resist layer.

17. The process of claim 16 wherein the electron beam accelerating voltage is about 2 KV, the resist layer is about 20 nm thick, the current of the electron beam is about 200 microamperes, the electron beam diameter is about 3 mm, the nDCM is a 4 Division Complementary Mask (4DCM) that is fabricated from monocrystalline silicon with the membranes being a portion of a conductive layer formed thereon and having a thickness of about 100 nm.

18. The process of claim 17 wherein the struts of the 4DCM are monocrystalline silicon, are thicker than the membranes and act as heat sinks for the membranes, and the membranes are a conductive layer of one of a group consisting of doped silicon, silicide, and a conductor.

19. The system of claim 16 wherein the nonmetallic conductor layer is one of a group comprising a hydro-carbon resist like material and amorphous carbon.

20. The system of claim 19 wherein the nonmetallic conductor layer is about 50 nm thick.

21. A system for forming a pattern on an electron sensitive resist layer covering a chip semiconductor wafer having a plurality of x individual areas into each of which an individual integrated circuit is to be formed comprising:
an electron beam system characterized by an accelerating voltage of about 0.5 to about 5 KV, an electron current of about 50 to about 800 microamperes, the beam having a diameter of about 1 to about 9 mm, and fine deflectors for adjusting tilt of the electron beam;
a first mask semiconductor wafer that comprises a plurality of x individual areas that each contain a portion of a pattern that is to be transferred to a portion of the resist layer covering an individual x area of the chip semiconductor wafer, the first mask semiconductor wafer comprising n Division Complementary Masks (nDCMs), where n is an integer of 2 or greater and is less than x, each of the nDCMs comprises n of the x individual areas of the first mask semiconductor wafer, each of the individual x areas of the mask semiconductor wafer being the same size and shape as each individual x area of the chip semiconductor wafer, each of the nDCMs having struts that support a membrane that has formed therein a pattern that is to be transferred to the resist layer, the thickness of each membrane being about 50 to about 500 nm, and the first mask semiconductor wafer and the chip semiconductor wafer being spaced about 10 to about 300 microns from each other and being positioned in the path of the electron beam;
the resist layer having thickness of about 10 to about 300 nm;
a nonmetallic conductor layer having a thickness of about 50 nm and lying under the resist layer;
a distortion sensor having an output, said distortion sensor being adapted to sense alignment distortion errors between the membranes of the nDCM and the semiconductor wafer and provide at the output thereof signals representative of the alignment distortion errors between the membranes of the nDCMs and chip semiconductor wafer; and
a system control unit having an input coupled to the output of the distortion sensor for controlling overall operation of the system, said system control unit being adapted to generate from signals received from the distortion sensor a distortion error correction signal at an output thereof that is coupled to inputs of the fine deflectors whereby the tilt of the electron beam is adjusted such that distortions in the membranes of the nDCM and the semiconductor wager are compensated for so as to minimize image placement errors.

22. The system of claim 21 wherein the electron beam accelerating voltage is about 2 KV, the electron beam current is about 200 microamperes, the electron beam diameter is about 3 mm, the thickness of the membranes of the nDCM is about 100 nm; the nDCM being spaced about 50 microns from the resist layer, the thickness of the resist layer being about 20 nm; and each of the nDCMs is a 4 Divisional Complementary Mask (4DCM); and
the four nDCMs of each two by two group each contain one-fourth of a pattern to be transferred to the resist layer with the four nDCMs containing all of the pattern.

23. The system of claim 21 wherein the electron beam accelerating voltage is about 2 KV, the electron beam current is about 200 microamperes, the electron beam diameter is about 3 mm, the thickness of the membranes of the nDCM is about 100 nm, the nDCM being spaced about 50 microns from the resist layer, the thickness of the resist layer being about 20 nm; and each of the nDCMs is a 4 Divisional Complementary Mask (4DCM);
the four nDCMs of each two by two group each contain the same first one-quarter of a pattern to be transferred to resist layer;
second, third, and fourth mask semiconductor wafers being essentially the same size and shape as the first mask wafer;
the four DCMs of the second mask semiconductor wafer each containing the same second one-quarter of a pattern to be transferred to the resist layer;
the four DCMs of the third mask semiconductor wafer each containing the same third one-quarter of a pattern to be transferred to the resist layer; and
the four DCMs of the fourth mask semiconductor wafer each containing the same fourth on-quarter of a pattern to be transferred to the resist layer.

24. In the manufacture of silicon integrated circuits, a process of patterning an electron sensitive resist layer covering a nonmetallic conductor layer that covers a chip semiconductor wafer comprising a plurality of individual x areas in which integrated circuit chips are to be formed comprising the steps of:
using an electron beam system having an accelerating voltage in the range of about 0.5 to about 5 KV with a beam current in the range of about 50 to 800 microamperes and with the beam diameter being in the range of about 1 to 9 mm, aligning a semiconductor mask wafer that comprises a plurality of x individual areas that each contain a portion of a pattern that is to be transferred to a portion of the resist layer covering an individual x area of the chip semiconductor wafer with the chip semiconductor wafer, the semiconductor mask wafer comprises a plurality of n Division Complementary Masks (nDCMs), where n is an integer of 2 or greater and is less than x, each of the nDCMs comprises n of the x individual areas of the semiconductor mask wafer, each of the individual x areas of the mask semiconductor wafer being the same size and shape as each individual x area of the chip semiconductor wafer, each of the nDCMs having struts that support a membrane that has formed therein a pattern that is to be transferred to the resist layer, the thickness of each membrane being about 50 to about 500 nm, the thickness of the resist layer being about 10 to 300 nm, and the first mask semiconductor wafer and the chip semiconductor wafer being spaced about 10 to about 300 microns from each other and being positioned in the path of the electron beam;
sensing alignment distortion errors between the mask semiconductor and the chip semiconductor wafer and generating therefrom an alignment distortion error correction signal;
applying the alignment distortion error signal to fine deflectors of the electron beam system that control tilt of the electron beam so as to adjust the tilt of the beam to compensate for alignment distortions between the mask semiconductor wafer and the chip semiconductor wafer so as to minimize image placement errors; and
scanning the electron beam across the membrane with the accelerating voltage in the range of about 0.5 to about 5 KV, a beam current in the range of about 50 to 800 microamperes and with the beam diameter being in the range of about 1 to 9 mm, whereby the pattern is transferred to the resist layer.

25. The process of claim 24 wherein each of the areas of the mask semiconductor wafer is a 4DCM and there are a total of four of the mask semiconductor wafers with the first of same containing within the membranes a first one-fourth of the pattern to be transferred to the x areas of the chip semiconductor wafer, with the second of same containing within the membranes a second one-quarter of the pattern to be transferred to the x areas of the chip semiconductor wafer, with the third of same containing within the membranes a third one-quarter of the pattern to be transferred to the x areas of the chip semiconductor wafer, and with the fourth of same containing within the membrane a fourth one-quarter of the pattern to be transferred to the x area of the chip semiconductor wafer, and the process further comprising the steps of:
aligning the first mask semiconductor wafer with the chip semiconductor wafer and then sensing alignment distortions errors between them and generating therefrom an alignment distortion error correction signal;
applying the alignment distortion error correction signal to fine deflectors of the electron beam system that control tilt of the electron beam so as to adjust the tilt of the beam to compensate for distortions in the first mask semiconductor wafer and the chip semiconductor wafer so as to minimize image placement errors;
scanning the electron beam across the chip semiconductor wafer whereby the pattern in the membranes of the first mask semiconductor wafer is transferred to the resist layer;
aligning the second mask semiconductor wafer with the chip semiconductor and then sensing distortions in both and generating therefrom a distortion error signal;
applying the error correction signal to fine deflectors of the electron beam system that control tilt of the electron beam so as to adjust the tilt of the beam to compensate for distortions in the second mask semiconductor wafer and the chip semiconductor wafer so as to minimize image placement errors;
scanning the electron beam across the chip semiconductor wafer whereby the pattern in the membranes of the second mask semiconductor wafer is transferred to the resist layer;
aligning the third mask semiconductor wafer with the chip semiconductor wafer and then sensing distortions in both and generating therefrom a distortion error correction signal;
applying the error correction signal to fine deflectors of the electron beam system that control tilt of the electron beam so as to adjust tilt of the beam to compensate for distortions in the third mask semiconductor wafer so as to minimize image placement errors;
scanning the electron beam across the chip semiconductor wafer whereby the pattern in the membranes of the third mask semiconductor is transferred to the resist layer;
aligning the fourth mask semiconductor wafer with the chip semiconductor wafer and then sensing distortions in both and generating therefrom a distortion error correction signal;
applying the error correction signal to fine deflectors of the electron beam that controls tilt of the electron beam so as to adjust the tilt of the beam to compensate for distortions in the fourth mask semiconductor wafer and the chip semiconductor wafer so as to minimize image placement errors; and
scanning the electron beam across the chip semiconductor wafer whereby the pattern in the membranes of the fourth mask semiconductor is transferred to the resist layer such that the entire pattern is transferred to the resist layer.

26. The process of claim 24 wherein each of the x areas of the mask semiconductor wafer is a 4DCM with the four membranes of each two by two array of the x areas each containing a separate one-quarter of the pattern to be transferred to each of the x areas of the chip semiconductor wafer, and the process further comprising the steps of:
aligning the mask semiconductor with the chip semiconductor wafer and then sensing distortions in both and generating therefrom a distortion error correction signal;
applying the error correction signal to fine deflectors of the electron beam system that control tilt of the electron beam so as to adjust the tilt of the beam to compensate for distortions in the mask semiconductor wafer and the chip semiconductor wafer so as to minimize image placement errors;
scanning the electron beam across the chip semiconductor wafer whereby the pattern in the membranes of the mask semiconductor wafer is transferred to the resist is so transferred; and
repeating the alignment of the mask semiconductor wafer and the chip semiconductor wafer a second, third and fourth times and generating second, third, and fourth scannings of the electron beam across the chip semiconductor wafer such that the entire pattern is transferred to the resist layer.

27. The system of claim 21 wherein the chip semiconductor and the mask semiconductor wafer are the same size and shape.

28. A system for forming a pattern on a resist layer covering a chip semiconductor wafer having a plurality of x individual areas into each of which an individual integrated circuit is to be formed comprising:
a first mask semiconductor wafer that comprises a plurality of x individual areas that each contain at least a first portion of a pattern that is to be transferred to a portion of the resist layer covering an individual x area of the chip semiconductor wafer;
the first mask semiconductor wafer comprising n Division Complementary Masks (nDCMs), where n is an integer of 2 or greater and is less than x, each of the nDCMs comprises n of the x individual areas of the first mask semiconductor wafer;
each of the individual x areas of the mask semiconductor wafer being the same size and shape as each individual x area of the chip semiconductor wafer; and
each of the nDCMs having struts that support a membrane that has formed therein a pattern that is to be transferred to the resist layer.

29. The system of claim 28 further comprising:
at least a second mask semiconductor wafer that comprises a plurality of x individual areas that each contains a different portion of a pattern that is to be transferred to a portion of the resist layer covering an individual x area of the chip semiconductor wafer;
the second mask semiconductor wafer comprising a plurality of n Division Complementary Masks (nDCMs), where n is an integer of 2 or greater and is less than x, and each of the nDCMs comprises n of the x individual areas of the second mask semiconductor wafer;
each of the individual x areas of the mask semiconductor wafer being the same size and shape as each individual x area of the chip semiconductor wafer; and
each of the nDCMs having struts that support a membrane that has formed therein a pattern that is to be transferred to the resist layer.
